(19) United States
(12) Patent Application Publication
(10) Pub. No.: US 2017/0058429 A1
(43) Pub. Date: Mar. 2, 2017

(54) Method for Growing Sapphire Crystal

(71) Applicants: Yu-Feng Chuang, Bade City (TW); Ying-Jen Chuang, Bade City (TW)

(72) Inventor: Yu-Feng Chuang, Bade City (TW)

(21) Appl. No.: 14/841,744

(22) Filed: Sep. 1, 2015

(51) Int. Cl. C30B 29/20; C30B 11/02

(52) U.S. Cl. CPC C30B 29/20; C30B 11/02

(57) ABSTRACT

A method includes grinding alumina powder into alumina particles with ultrafine particle powder, performing a purification process so that the alumina particles have a purity greater than 99.999%, processing the alumina particles by a spray dryer, processing the alumina particles by a sheet molding compound to produce an alumina material, and placing the alumina material in a vacuum super high temperature furnace to have a crystal growth which includes placing the alumina material in a predetermined crucible in the vacuum super high temperature furnace, preburning the alumina material to form a half-baked alumina cake, heating and increasing a temperature of the alumina cake so that the alumina cake is disposed at a melted state until the crystal growth is finished, and curing the alumina cake that is melted so as to form a sapphire crystal.

### BACKGROUND OF THE INVENTION

1. Field of the Invention

The present invention relates to a sapphire panel industry and, more particularly, to a method for growing a sapphire crystal.

2. Description of the Related Art

A conventional medium-size panel of a smart phone is made of glass material. The glass is worked by grinding and chemical stiffening to enhance its mechanical strength and wear resistance. However, the glass is easily scratched or broken. The sapphire can be used as a material for making the panel. The sapphire itself has a greater hardness, is wear resistant and can prevent from being scratched so that when the sapphire is used in the conventional medium-size touch panel of the smart phone, the sapphire can increase the lifetime of the touch panel and enhance the aesthetic quality of the touch panel. In addition, the sapphire panel can efficiently control the optical quality, has a greater mechanical strength, has a greater stiffness, has a greater abrasion resistance, has a higher thermal conductivity, can tolerate high temperature, and is corrosion resistant. Thus, the sapphire is available for parts of high strength. A conventional method for making a sapphire substrate comprises taking a sapphire crystal stick as raw material, cutting the sapphire crystal stick into multiple substrates, cutting the substrates into rectangular panels of various sizes, trimming edges of the rectangular panels, chamfering the rectangular panels, performing a double-faced grinding procedure, and performing a polishing procedure, thereby forming the ultimate panel. However, the conventional method for making the sapphire panel has a complicated procedures, thereby greatly increasing the cost and time during fabrication of the sapphire panel. In addition, the sapphire crystal stick has a greater hardness so that it is difficult to work the sapphire crystal stick, thereby decreasing the working efficiency. Further, the sapphire crystal stick has an elongate cylindrical shape, and the panel has a rectangular shape, so that the sapphire crystal stick has to be cut and worked to have a predetermined thickness, size and shape, thereby greatly increasing the cost and working time of fabrication.

### BRIEF SUMMARY OF THE INVENTION

In accordance with the present invention, there is provided a method for growing a sapphire crystal, comprising grinding alumina (Al₂O₃) powder into alumina particles with ultrafine particle powder, performing a purification process so that the alumina particles have a purity greater than 99.999%, mixing the alumina particles with a frit reduce according to a determined proportion, processing the alumina particles by a spray dryer, processing the alumina particles by a sheet molding compound to produce an alumina material, and placing the alumina material in a vacuum super high temperature furnace to have a crystal growth. The crystal growth includes placing the alumina material from the sheet molding compound in a predetermined crucible in the vacuum super high temperature furnace, prebuming the alumina material to form a half-baked alumina cake, heating and increasing a temperature of the alumina cake so that the alumina cake is disposed at a melted state until the crystal growth is finished, and curing the alumina cake that is melted so as to form a sapphire crystal.

Preferably, the alumina material has a γ or α crystal phase and has a powder diameter under 500 nanometers, and the frit reduce has a powder diameter under 100 nanometers.

Preferably, the alumina material may be added with an alumina material which has a γ or α crystal phase and has a powder diameter under 40 nanometers, with a weight proportion of 6% to 10%.

Preferably, after the step of processing the alumina particles by a spray dryer, the method further comprises adding a binder into the alumina particles, with a weight proportion of 1% to 3%.

According to the primary advantage of the present invention, the method of the present invention saves the growth time of the sapphire crystal.

According to another advantage of the present invention, the sapphire crystal has a lower cost of fabrication and a higher yield rate.

According to a further advantage of the present invention, the mass and size of the sapphire crystal is not limited.

According to a further advantage of the present invention, the crystal growth is directly finished to form the sapphire crystal with a predetermined size so as to largely save the subsequent cutting time and the cost of material.

Further benefits and advantages of the present invention will become apparent after a careful reading of the detailed description with appropriate reference to the accompanying drawings.

### BRIEF DESCRIPTION OF THE SEVERAL VIEWS OF THE DRAWING

FIG. 1 is a perspective view of a sapphire crystal in accordance with the preferred embodiment of the present invention.

### DETAILED DESCRIPTION OF THE INVENTION

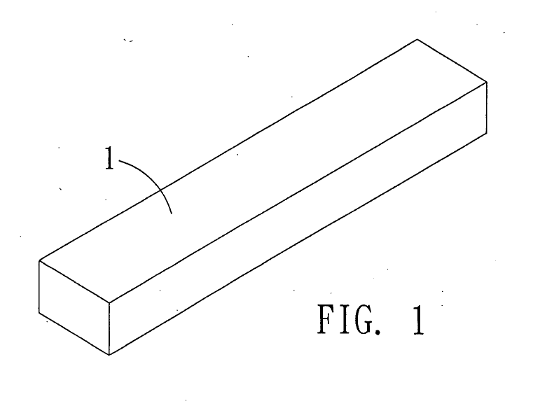

Referring to FIG. 1, a sapphire crystal 1 in accordance with the preferred embodiment of the present invention is made to have a cubic configuration. Preferably, the sapphire crystal 1 has the shape of a cuboid. Alternatively, the sapphire crystal 1 has the shape of a cube.

A method in accordance with the present invention is used for growing the sapphire crystal 1 as shown in FIG. 1 and comprises grinding alumina (Al₂O₃) powder into alumina particles with ultrafine particle powder, performing a purification process so that the alumina particles have a purity greater than 99.999%, mixing the alumina particles with a frit reduce according to a determined proportion, processing the alumina particles by a spray dryer, adding an organic binder into the alumina particles, processing the alumina particles by a sheet molding compound to produce an alumina material, and placing the alumina material in a vacuum super high temperature furnace to have a crystal growth.

In the preferred embodiment of the present invention, the frit reduce is lithium oxide (LiO₂), and the mixed proportion in the step of mixing the alumina particles is under 3500 ppmwt %.

The crystal growth includes placing the alumina material from the sheet molding compound in a predetermined crucible in the vacuum super high temperature furnace, preburning the alumina material to form a half-baked alumina cake, heating and increasing a temperature of the alumina cake so that the alumina cake is disposed at a melted state until the crystal growth is finished, and curing the alumina cake that is melted so as to form the sapphire crystal 1.

In the step of grinding alumina (Al₂O₃) powder, the alumina powder is pulverized and ground by a chemical additive into alumina particles with ultrafine particle powder, such as particles of ten nanometers. Pulverizing and grinding procedures are important in making the powder. The pulverizing work is a rough grinding procedure. The grinding work is used to obtain particles with a diameter smaller than one millimeter. A pulverizer is used to execute the pulverizing work. A mill ball is used to execute the grinding work. For traditional ceramic powder, the pulverizing and grinding operations are the only way to get this powder. But for a new generation of ceramic powder, the pulverizing and grinding operations possibly contain diverse purposes, including: breaking up the aggregate powder, reducing the aggregate powder or making the powder become ultimate particles; reducing the powder diameter, eliminating particles that are too coarse, and making a particle size distribution being within a certain range, so as to satisfy the required specification for the particle size. A large amount of fine powder significantly increases the specific surface area and reaction activity of the powder. The pulverizing action is a transfer process of energy. That is, the dynamic energy or mechanic work of the pulverizing machine produces hitting, rolling and rubbing between powder particles to crash, break the powder or form corners on the powder, so that the specific surface area of the powder is increased, and the surface free energy is also increased. Thus, we can say that, the pulverizing action is a energy transfer process wherein the mechanic energy is converted into a surface energy. The chemical composition of the powder relates to various physical properties of the alumina ceramic powder. The impurity contained in the material will cause different influences to the sintering process.

The particle size and structure decide the density and formation of the body of the material. When the particle size is smaller and the structure is more incomplete, the activity is greater to facilitate the sintering process. In addition, when the particle size is smaller, the diameter of the particle is decreased so that the speed is increased during the spread mass transfer process. On the other hand, when the particle size is smaller, the surface area is larger so that the surface spread is increased. Thus, the surface spread is faster than the spatial spread. Moreover, the sintering rate is determined by the driving force, the mass transfer rate and the contact area, and the above-said three factors are closely related to the powder diameter. Thus, the grinding step can effectively save the time of the subsequent high temperature crystal growth and improve the crystal quality.

In the purification process, the alumina particles are purified so that the alumina particles have a purity greater than 99.999%. In general, the ceramic material, natural or synthetic, has a low purity. Thus, the uniformity, stability and reliability of the quality of the ceramic material are worse than that of the metallic material and the high molecule material. By the purification process of the present invention, the alumina particles are purified to have a purity greater than 99.999% so as to enhance the uniformity, stability and reliability of the material.

In the step of processing the alumina particles by a spray dryer, the material of the alumina particles is added with a proper solvent and is stirred by a strong pump to form a raw material glue. Then, the raw material glue is pressurized by a high pressure pump. Then, the raw material glue is delivered into a spray dryer nozzle. Then, the raw material glue is injected from the spray dryer nozzle into a high temperature dry tower. At this time, the hot air of a high speed heat flow in the high temperature dry tower dries the raw material glue instantaneously into alumina particles with uniform sizes. Then, the alumina particles are gathered. The nanometer powder suspends in the air and will be inhaled into the human body, thereby causing danger to the human health. In the commercial application of the nanometer product, the gathering of powder is a key technology. In the conventional high temperature manner, aggregate gathering will gather and enlarge the nanometer powder so that the nanometer powder easily loses the nanometer size. In the present invention, the nanometer powder is gathered under a low temperature procedure so that the particles are gathered during the secondary aggregate to form particles of several tens of micrometers. Thus, the alumina powder particles are purified to filter the impurities and maintain the size of the original nanometer powder. In such a manner, the method of the present invention produces alumina powder with high purity, low impurity contents and smaller size.

In the step of processing the alumina particles by a sheet molding compound, the alumina particles are compressed to have a predetermined shape. The characteristic is in that, the binder content is low so that the body formed by the sheet molding compound can be directly preburned without drying. In addition, the body has little contraction so that it can be produced automatically. In practice, the alumina particles, formed after the step of processing the alumina particles by a spray dryer, are placed in a die. Then, the alumina particles are added with a small amount of organic binder. Then, the alumina particles are pressed by a pressing machine to form a body with predetermined thickness, size and shape. In such a manner, the alumina particles in the die approach each other under an external force, and are connected solidly and firmly by an internal friction force to maintain a determined shape. Thus, the step of processing the alumina particles by a sheet molding compound is operated easily and conveniently, has a short cycle, has a high efficiency and can be produced automatically. In addition, the body has a greater density, has a precise size, has little contraction, has a greater mechanic strength and has a better electric capacity.

In the crystal growth, the alumina body, formed after the step of processing the alumina particles by a sheet molding compound, is prebumed to form a half-baked alumina cake. In practice, the alumina body is placed in a predetermined crucible in the vacuum super high temperature furnace to perform the preburning process. The vacuum super high temperature furnace includes the crucible, a heat generator, an insulation device, and a cooling device, made of molybdenum, zirconium, platinum and other materials. The vacuum super high temperature furnace is a conventional structure and will not be further described in detail. The temperature of the present invention is preset at about 2040° C. to 2100° C. The required time depends on the volume. The present invention, as compared to the conventional technology, can save the time and energy, and has a stable quality. In addition, the mass and size of the crystal are not restricted. The inner edge of the crucible is designed according to the panel size that is to be produced. The length of the crucible is controlled by the die so as to grow the crystal with a predetermined size. Crystal seeds are placed in the crucible. The crystal is designed to grow in the direction of A-axis or C-axis. The preburning temperature is preset to exceed 1600° C., thereby eliminating tiny organic substances, impurities, bubbles, etc., and thereby producing a compact specific gravity. The organic substances, impurities, etc., are usually lighter and easily float so that they can be eliminated under the high temperature. The vacuum super high temperature furnace has an air outlet to draw and drain gases with impurities. Then, an inert gas is introduced into the vacuum super high temperature furnace, and the temperature is increased to heat the half-baked alumina cake so that the alumina cake is disposed at a melted state. When the crystal growth is finished according to the predetermined size and shape of the crucible. Then, the alumina cake is cured to form the sapphire crystal. Thus, the present invention can save the crystal growth time of the sapphire and has a lower cost. The mass and size of the crystal are not restricted. The crystal growth is directly finished to form the sapphire crystal with a predetermined size. Then, the sapphire crystal is cut and divided to have the thickness of a panel. Then, the sapphire crystal is abraded and polished to form a sapphire panel. Thus, the present invention can largely save the subsequent cutting time and the cost of material.

In the preferred embodiment of the present invention, the alumina material has a γ or α crystal phase and has a powder diameter under 500 nanometers, and the frit reduce has a powder diameter under 100 nanometers.

In the preferred embodiment of the present invention, the alumina material may be added with an alumina material which has a γ or α crystal phase and has a powder diameter under 40 nanometers, with a weight proportion of 6% to 10%, so as to shorten the manufacturing time and enhance the product quality.

In the preferred embodiment of the present invention, the binder includes polyvinyl alcohol (PV), starch dextrin, etc., with a weight proportion of 1% to 3%, so as to enhance the binding between the material powders.

Accordingly, the method of the present invention saves the growth time of the sapphire crystal. In addition, the sapphire crystal has a lower cost of fabrication and a higher yield rate. Further, the mass and size of the sapphire crystal is not limited. Further, the crystal growth is directly finished to form the sapphire crystal with a predetermined size so as to largely save the subsequent cutting time and the cost of material.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A method for growing a sapphire crystal, comprising:
grinding alumina (Al₂O₃) powder into alumina particles with ultrafine particle powder;
performing a purification process so that the alumina particles have a purity greater than 99.999%;
mixing the alumina particles with a frit reduce according to a determined proportion;
processing the alumina particles by a spray dryer;
processing the alumina particles by a sheet molding compound to produce an alumina material; and
placing the alumina material in a vacuum super high temperature furnace to have a crystal growth;
wherein:
the crystal growth includes:
placing the alumina material from the sheet molding compound in a predetermined crucible in the vacuum super high temperature furnace;
preburning the alumina material to form a half-baked alumina cake;
heating and increasing a temperature of the alumina cake so that the alumina cake is disposed at a melted state until the crystal growth is finished; and
curing the alumina cake that is melted so as to form a sapphire crystal.

2. The method of claim 1, wherein the alumina material has a γ or α crystal phase and has a powder diameter under 500 nanometers, and the frit reduce has a powder diameter under 100 nanometers.

3. The method of claim 1, wherein the alumina material may be added with an alumina material which has a γ or α crystal phase and has a powder diameter under 40 nanometers, with a weight proportion of 6% to 10%.

4. The method of claim 1, wherein after the step of processing the alumina particles by a spray dryer, the method further comprises adding a binder into the alumina particles, with a weight proportion of 1% to 3%.
